(19) United States
(12) Patent Application Publication
(10) Pub. No.: US 2016/0329361 A1
(43) Pub. Date: Nov. 10, 2016

(54) PIXEL STRUCTURE, MANUFACTURING METHOD THEREOF AND DISPLAY PANEL

(71) Applicant: SHENZHEN CHINA STAR OPTOELECTRONICS TECHNOLOGY CO., LTD, Guangdong (CN)

(72) Inventor: Peng DU, Shenzhen, Guangdong (CN)

(21) Appl. No.: 14/782,192

(22) PCT Filed: Jan. 22, 2015
(86) PCT No.: PCT/CN2015/071288

§ 371 Date: Apr. 29, 2016

(30) Foreign Application Priority Data
Jan. 27, 2014 (CN) 201410041106.6

(51) Int. Cl. H01L 27/12; H01L 21/28; H01L 21/311; H01L 21/3105; H01L 21/027

(52) U.S. Cl. CPC H01L 27/1288; H01L 27/1248; H01L 21/31055; H01L 21/0274; H01L 21/31144; H01L 21/28158

(57) ABSTRACT

The present invention discloses a pixel structure, a manufacturing method thereof and a display panel. The method for manufacturing the pixel structure comprises: forming a patterned first metal layer on a substrate; and forming a planarized first insulating layer on the substrate, in which the first insulating layer is configured to fill gaps of the first metal layer and expose the surface of the first metal layer. Thus, the segment difference of the first metal layer can be eliminated, and hence the adverse effects on the manufacturing of subsequent layers due to segment difference can be eliminated. Therefore, the first metal layer thicker than that of the traditional method can be prepared. Consequently, the wiring load of large-size panels can be effectively reduced; the resistance of signal lines can be reduced; the signal delay can be reduced; and the display quality can be improved.

### FIELD OF THE INVENTION

The present invention relates to the technical field of liquid crystal display, in particular to a method for manufacturing a pixel structure, the pixel structure and a display panel.

### BACKGROUND OF THE INVENTION

Currently, large-size and high-resolution display panel has become a development trend of thin-film transistor liquid crystal displays (TFT-LCDs). However, when the size is increased, the load of signal lines is also increased, and hence the signal delay can be caused and the display quality can be severely affected. In order to solve the above problems, a method for increasing the thickness of metal layers to effectively reduce the resistance and reduce the load of signal lines is provided in the prior art. But along with the increase in the thickness of the metal layer, large segment difference will be produced after the patterning of the metal layer, and hence the manufacturing of subsequent layers can be affected. Particularly, the problems of breakage and the like of subsequent films at overline positions can be caused, and hence the product yield can be severely reduced.

In addition, a pixel electrode in a light transmission area of the traditional pixel structure tends to adopt a structure having the shape of a Chinese character ‘MI’ (Rice). That is to say, the light transmission area is formed by a plurality of strip pixel electrodes, and slit gaps are formed between the pixel electrodes. As slit portions are provided with no electrode, the electric field strength is weak, and hence the loss of partial penetration can be caused and the real quality can be reduced.

### SUMMARY OF THE INVENTION

The main objective of the present invention is to provide a pixel structure, a manufacturing method thereof and a display panel to effectively solve the problem of signal delay of large-size display panels and improve the display quality.

In order to achieve the above objective, the present invention provides a method for manufacturing a pixel structure, which comprises the following steps:

forming a patterned first metal layer on a substrate; and

forming a planarized first insulating layer on the substrate, in which the first insulating layer is configured to fill gaps of the first metal layer and expose a surface of the first metal layer.

Preferably, the step of forming the planarized first insulating layer on the substrate includes:

forming a first insulating layer for covering the first metal layer on the substrate, in which the first insulating layer is configured to fill the gaps of the first metal layer; and

planarizing the first insulating layer, so that the surface of the first metal layer is exposed by the first insulating layer.

Preferably, the step of planarizing the first insulating layer includes:

coating a negative photoresist layer on the first insulating layer;

performing development by taking the first metal layer as a mask, and removing the negative photoresist layer on the first metal layer to expose the first insulating layer; and

etching the first insulating layer, and removing the exposed first insulating layer on the first metal layer to expose the surface of the first metal layer.

Preferably, after the step of forming the planarized first insulating layer on the substrate, the method further comprises:

forming a second insulating layer provided with a plurality of recesses on the first insulating layer of a light transmission area; and

forming an integral pixel electrode layer on the second insulating layer, in which the pixel electrode layer integrally covers the second insulating layer.

Preferably, the recesses are elongated; and the plurality of recesses are arranged in parallel.

Preferably, the second insulating layer includes a gate insulator (GI) layer and a passivation (PAV) layer.

The present invention further provides a pixel structure disposed on a substrate, which comprises a patterned first metal layer and a planarized first insulating layer formed on the substrate, in which the first insulating layer is configured to fill gaps of the first metal layer and expose a surface of the first metal layer.

Preferably, the pixel structure is provided with a light transmission area and further comprises a second insulating layer and a pixel electrode layer, in which

the second insulating layer is formed on the first insulating layer of the light transmission area and provided with a plurality of recesses; and

the pixel electrode layer is an integral structure and integrally covers the second insulating layer.

Preferably, the recesses are elongated; and the plurality of recesses are arranged in parallel.

The present invention further provides a display panel, which comprises a substrate and pixel structures disposed on the substrate, wherein the pixel structure includes a patterned first metal layer and a planarized first insulating layer formed on the substrate; and the first insulating layer is configured to fill gaps of the first metal layer and expose a surface of the first metal layer.

The method for manufacturing the pixel structure, provided by the present invention, allows the first insulating layer to fill the gaps of the first metal layer and expose the first metal layer by the forming of the planarized first insulating layer, eliminates the segment difference of the first metal layer, and hence eliminates the adverse effects on the manufacturing of subsequent layers due to segment difference. Therefore, the first metal layer thicker than that of the traditional method can be prepared. Consequently, the wiring load of large-size panels can be effectively reduced; the resistance of signal lines can be reduced; the signal delay can be reduced; and the display quality can be improved.

### BRIEF DESCRIPTION OF THE DRAWINGS

FIG. 1 is a sectional view of an embodiment of the pixel structure provided by the present invention;

FIG. 2 is a sectional view of a light transmission area of a pixel structure in the prior art;

FIG. 3 is a sectional view of a light transmission area of the pixel structure provided by the present invention;

FIG. 4 is a flowchart of a first embodiment of the method for manufacturing the pixel structure, provided by the present invention;

FIG. 5 is a specific flowchart of the step S103 in FIG. 4;

FIG. 6 is a schematic structural view of a product obtained after the step of forming a patterned first metal layer on a substrate in the present invention;

FIG. 7 is a schematic structural view of a product obtained after the step of forming a first insulating layer and a photoresist layer on the substrate in the present invention;

FIG. 8 is a schematic structural view of a product obtained after the development of the pixel structure in FIG. 7 in the present invention;

FIG. 9 is a schematic structural view of a product obtained after the step of forming a planarized first insulating layer on the substrate in the present invention;

FIG. 10 is a flowchart of a second embodiment of the method for manufacturing the pixel structure, provided by the present invention; and

FIG. 11 is a specific flowchart of the step S304 in FIG. 10.

Further description will be given to the implementation of the objective, the functional features and the advantages of the present invention with reference to the embodiments and the accompanying drawings.

### DETAILED DESCRIPTION OF THE PREFERRED EMBODIMENTS

It should be understood that the preferred embodiments described herein are only provided for the illustration of the present invention and not for the purpose of limiting the present invention.

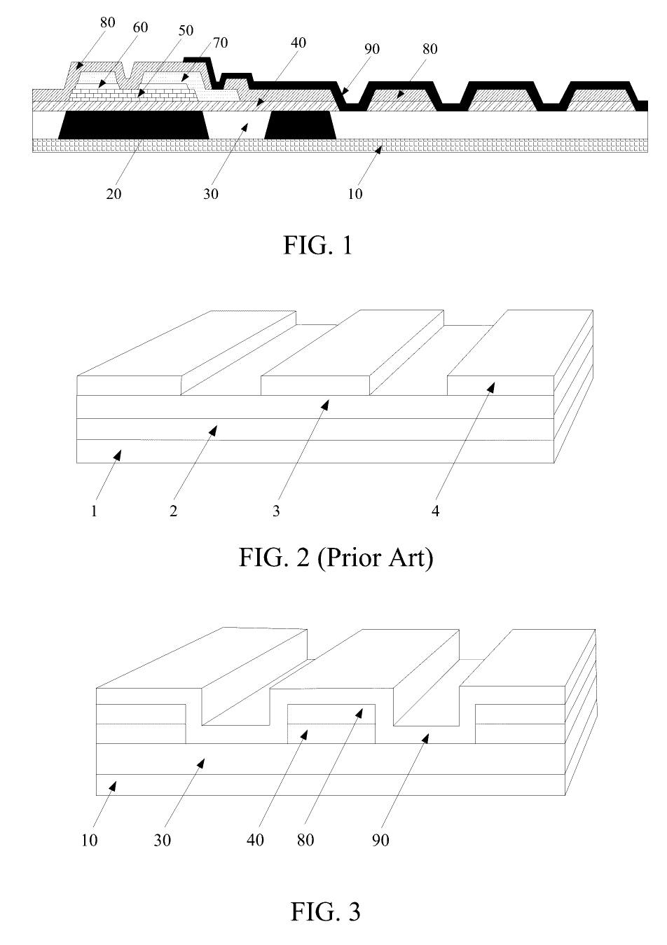

As illustrated in FIG. 1, an embodiment of a pixel structure provided by the present invention is provided. The pixel structure is disposed on a substrate 10 and comprises a patterned first metal (M1) layer 20, a planarized first insulating layer 30, a GI layer 40, a semiconductor layer 50, source/drain electrodes 60, a second metal (M2) layer 70, a PAV layer 80 and a pixel electrode layer 90.

The M1 layer 20 is provided with a plurality of gaps after patterned, and hence segment difference is formed. The first insulating layer 30 is configured to fill the gaps and expose the surface of the M1 layer 20. Moreover, the surface of the first insulating layer is preferably parallel to the surface of the first metal layer.

Wherein, the M1 layer 20 is formed on the substrate 10 by deposition and other means and is patterned. The M1 layer 20 may be made from metal or alloy such as Cr, W, Ti, Ta and Mo. The thickness of the M1 layer 20 is relatively large and can reach twice or more of the thickness of an M1 layer 20 in the conventional pixel structure. Thus, the resistance can be effectively reduced, and the signal delay can be reduced. As the M1 layer 20 is relatively thick, large segment difference can be formed in the patterned M1 layer 20 due to gaps.

The first insulating layer 30 may be a GI layer and may be made from silicon nitride (SiNx), silicon oxide (SiOx), etc. The first insulating layer 30 is formed on the entire substrate 10 by deposition and other means, covers the entire M1 layer 20, exposes the surface of the M1 layer 20 after planarization processing, and is preferably parallel to the surface of the M1 layer 20. Thus, the segment difference of the M1 layer 20 can be eliminated, and hence the adverse effects on the manufacturing of subsequent layers due to segment difference of the M1 layer 20 can be eliminated. Therefore, the M1 layer 20 thicker than that of the traditional method can be prepared.

Moreover, the GI layer 40 and the PAV layer 80 are combined into a second insulating layer of a light transmission area (right) of the pixel structure. The second insulating layer (the GI layer 40 and the PAV layer 80) is formed on the first insulating layer 30 of the light transmission area and provided with a plurality of recesses. The recesses are elongated, and the plurality of recesses are parallel to each other and uniformly arranged. Finally, the second insulating layer has a concave-convex three-dimensional (3D) structure on the whole. The pixel electrode layer 90 is an integral structure and integrally tiles and covers the second insulating layer (the GI layer 40 and the PAV layer 80). The recesses on the second insulating layer also have concave-convex 3D structures. The pixel electrode layer 90 is preferably made from transparent conductive material indium tin oxide (ITO).

Description is given with reference to FIGS. 2 and 3, in which FIG. 2 is a sectional view of a light transmission area of a pixel structure in the prior art and FIG. 3 is a sectional view of the light transmission area of the pixel structure provided by the present invention. As seen from FIG. 2, a GI layer 2 and a PAV layer 3 of the light transmission area in the prior art completely covers a substrate 1; and a pixel electrode layer 4 is formed on the PAV layer 3 and provided with a striped pattern, namely the pixel electrode layer 4 is provided with a plurality of alternately arranged strip electrodes. In the normal operation of the panel, portions with pixel electrodes have higher electric field strength, and corresponding penetration is higher; and portions among the pixel electrodes have lower electric field strength, and the loss of penetration can be caused.

As seen from FIG. 3, the light transmission area in the pixel structure provided by the present invention includes the first insulating layer 30, the second insulating layer (the GI layer 40 and the PAV layer 80) and the pixel electrode layer 90 formed on the substrate 10; and the entire light transmission area is integrally covered by the pixel electrode layer 90 which has a stripped (or concave-convex) 3D structure along with the recesses on the second insulating layer (the GI layer 40 and the PAV layer 80) below. In the normal operation of the panel, the pixel electrode layer 90 in convex portions of the second insulating layer (the GI layer 40 and the PAV layer 80) has high electric field strength and high penetration; and concave portions of the second insulating layer (the GI layer 40 and the PAV layer 80) are still covered by the pixel electrode layer 90. Compared with the prior art, the electric field strength of the area can be greatly improved, and hence the overall penetration of the pixel structure can be improved.

Accordingly, the pixel structure provided by the present invention allows the first insulating layer 30 to fill the gaps of the M1 layer 20 and expose the M1 layer 20 by the forming of the planarized first insulating layer 30, eliminates the segment difference of the M1 layer 20, and hence eliminates the adverse effects on the manufacturing of subsequent layers due to segment difference. Therefore, the M1 layer 20 thicker than that of the traditional method can be prepared. Consequently, the wiring load of large-size panels can be effectively reduced; the resistance of signal lines can be reduced; the signal delay can be reduced; and the display quality can be improved.

Meanwhile, by adoption of the above structure, the second insulating layer with the concave-convex (or stripped) 3D structure is formed on the first insulating layer 30 of the light transmission area via a common mask without increasing the extra cost. Therefore, the pixel electrode layer 90 may integrally tile and cover the second insulating layer, so that the pixel electrode layer 90 can completely cover the light transmission area, and hence the penetration of pixels can be improved and the display quality can be ultimately improved.

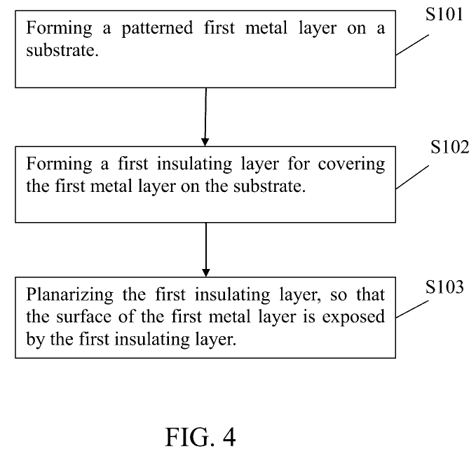

As illustrated in FIGS. 1, 4 and 5, a first embodiment of the method for manufacturing the pixel structure, provided by the present invention, is provided. The method for manufacturing the pixel electrode comprises the following steps:

S101: forming a patterned first metal layer on a substrate.

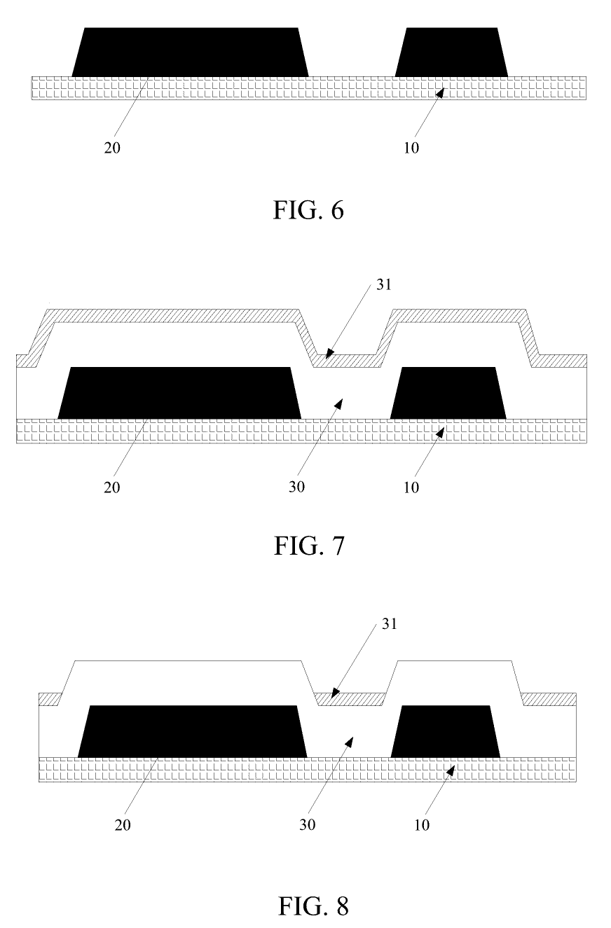

In the step S101, firstly, an M1 layer 20 is formed on a substrate 10 by deposition and other means. The M1 layer 20 may be made from metal or alloy such as Cr, W, Ti, Ta and Mo. The thickness of the M1 layer 20 is relatively large and can reach twice or more of the thickness of an M1 layer 20 in the conventional pixel structure. Thus, the resistance can be effectively reduced, and the signal delay can be reduced. Secondly, the M1 layer 20 is patterned to finally form a patterned M1 layer 20 as shown in FIG. 6. The patterned M1 layer 20 is provided with a plurality of gaps. As the M1 layer 20 is relatively thick, large segment difference can be formed in the patterned M1 layer 20.

S102: forming a first insulating layer for covering the first metal layer on the substrate.

As illustrated in FIG. 7, a first insulating layer 30 is formed on the entire substrate 10 by deposition and other means, covers the entire M1 layer 20, and fills the gaps of the M1 layer 20. The first insulating layer 30 may be a GI layer and may be made from SiNx, SiOx, etc.

S103: planarizing the first insulating layer, so that the surface of the M1 layer 20 is exposed by the first insulating layer.

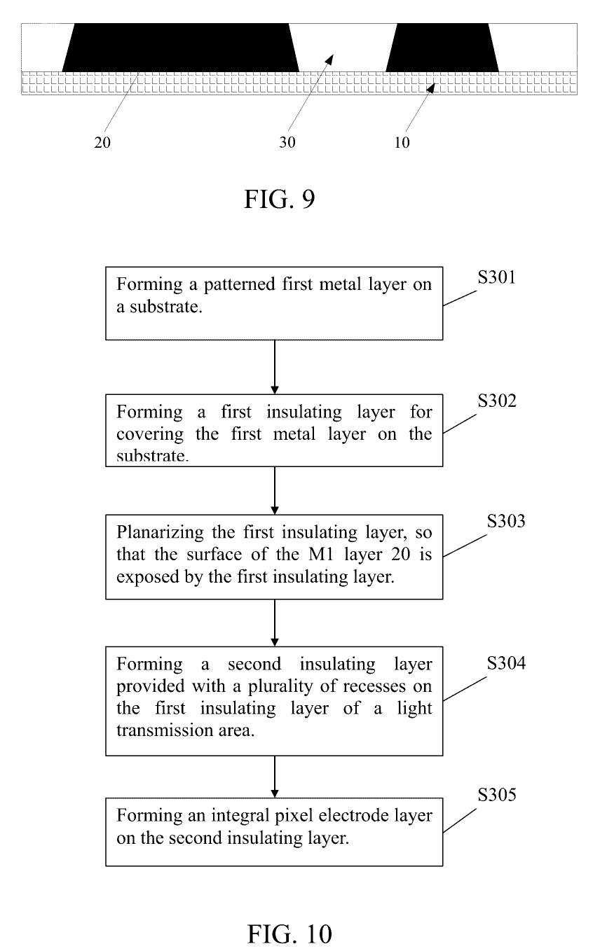

The first insulating layer 30 is planarized, so that the surface of the first insulating layer 30 is smooth and the surface of the M1 layer 20 is exposed, and hence the segment difference of the M1 layer 20 can be eliminated. The first insulating layer 30 is preferably parallel to the surface of the M1 layer 20 (as shown in FIG. 9).

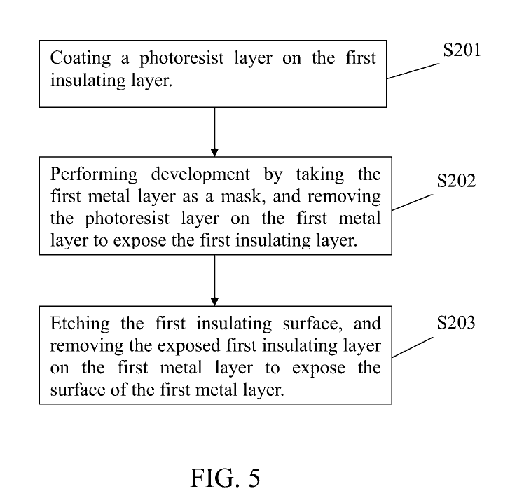

The manufacturing method in which the subsequent processes include the forming of the GI layer, the semiconductor layer, the source/drain electrodes, the second metal layer, the PAV layer and the pixel electrode layer is the same with the traditional 4 mask/5 mask manufacturing method. No further description will be given here.

Wherein, the planarization of the first insulating layer 30 is preferably performed according to the process in FIG. 5. In order to illustrate the process more intuitively, see also FIGS. 7 to 9 at the same time. FIGS. 6 to 9 illustrate the process of forming the planarized first insulating layer on the substrate in sequence. The specific processes are as follows:

S201: coating a photoresist layer on the first insulating layer.

As illustrated in FIG. 7, a coated photoresist layer 31 in the embodiment is a negative photoresist layer.

S202: performing development by taking the first metal layer as a mask, and removing the photoresist layer on the first metal layer to expose the first insulating layer.

Exposure and development are performed through the surface of the substrate 10 via ultraviolet light. The self-aligned manner is adopted and the formed patterned M1 layer 20 is taken as a mask. Therefore, no additional mask is required. After development, as illustrated in FIG. 8, the photoresist layer 31 on the M1 layer 20 is removed; the first insulating layer 30 is exposed; and portions without the M1 layer 20 are still covered by the photoresist layer 31.

S203: etching the first insulating surface, and removing the exposed first insulating layer on the first metal layer to expose the surface of the first metal layer.

The first insulating layer 30 is subjected to dry etching, and the exposed first insulating layer 30 on the M1 layer 20 is removed to expose the surface of the M1 layer 20. Subsequently, the first insulating layer 30 in an area without the M1 layer 20 is processed, so that the surface of the first insulating layer 30 is smooth. Preferably, the first insulating layer 30 is parallel to the surface of the M1 layer 20. The product obtained after planarization is finally as shown in FIG. 9.

Finally, the first insulating layer 30 fills the gaps of the patterned M1 layer 20. Thus, the segment difference formed in the patterned first metal layer can be eliminated, and hence the adverse effects on the manufacturing of the subsequent layers due to segment difference can be eliminated. Therefore, the M1 layer 20 thicker than the traditional method can be prepared, and hence the resistance can be effectively reduced and the signal delay can be reduced.

As illustrated in FIGS. 1, 10 and 11, a second embodiment of the method for manufacturing the pixel structure, provided by the present invention, is provided. The method for manufacturing the pixel structure comprises the following steps:

S301: forming a patterned first metal layer on a substrate.

In the step S301, firstly, an M1 layer 20 is formed on a substrate 10 by deposition and other means. The M1 layer 20 may be made from metal or alloy such as Cr, W, Ti, Ta and Mo. The thickness of the M1 layer 20 is relatively large and can reach twice or more of the thickness of an M1 layer 20 in the conventional pixel structure. Thus, the resistance can be effectively reduced, and the signal delay can be reduced. Secondly, the M1 layer 20 is patterned to finally form a patterned M1 layer 20 as shown in FIG. 2. The patterned M1 layer 20 is provided with a plurality of gaps. As the M1 layer 20 is relatively thick, large segment difference can be formed in the patterned M1 layer 20.

S302: forming a first insulating layer for covering the first metal layer on the substrate.

A first insulating layer 30 is formed on the entire substrate 10 by deposition and other means, covers the entire M1 layer 20, and fills the gaps of the M1 layer 20. The first insulating layer 30 may be preferably a GI layer and may be made from SiNx, SiOx, etc.

S303: planarizing the first insulating layer, so that the surface of the M1 layer 20 is exposed by the first insulating layer.

The first insulating layer 30 is planarized, so that the surface of the first insulating layer 30 is smooth and the surface of the M1 layer 20 is exposed, and hence the segment difference of the M1 layer 20 can be eliminated. The first insulating layer 30 is preferably parallel to the surface of the M1 layer 20.

S304: forming a second insulating layer provided with a plurality of recesses on the first insulating layer of a light transmission area.

The recesses are preferably elongated, and the plurality of recesses are parallel to each other and uniformly arranged on the second insulating layer.

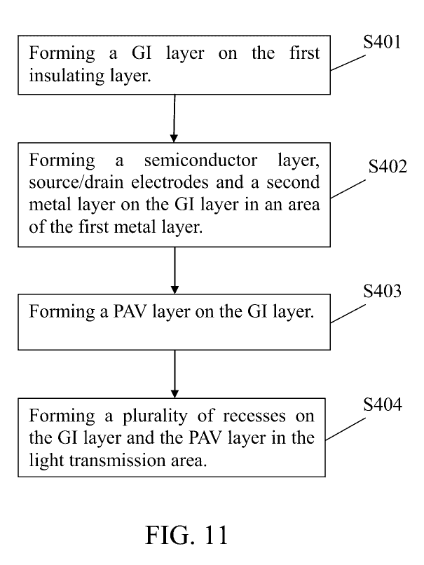

The second insulating layer preferably includes a GI layer 40 and a PAV layer 80. The specific processes of the step are as follows (as shown in FIG. 11):

S401: forming a GI layer on the first insulating layer.

After the planarized first insulating layer 30 is formed on the substrate 10, a GI layer 40 is formed on the first insulating layer 30.

S402: forming a semiconductor layer, source/drain electrodes and a second metal layer on the GI layer in an area of the first metal layer.

As illustrated in FIG. 1, a semiconductor layer 50, source/drain electrodes 60 and an M2 layer 70 are formed on the GI layer 40 in an area (left) of the first metal layer 20 in sequence.

S403: forming a PAV layer on the GI layer.

A PAV layer 80 covers the semiconductor layer 50, the source/drain electrodes 60 and the M2 layer 70.

S404: forming a plurality of recesses on the GI layer and the PAV layer in the light transmission area.

In the light transmission area (the right side in FIG. 1), the GI layer 40 and the PAV layer 80 are combined into a second insulating layer. A plurality of mutually parallel elongated recesses are formed on the GI layer 40 and the PAV layer 80 in the second insulating layer by dry etching and other manufacturing processes via a common mask. The first insulating layer 30 is exposed by the recesses. Finally, the second insulating layer has a concave-convex 3D structure on the whole.

After the recesses are formed on the second insulating layer, the next step is executed:

S305: forming an integral pixel electrode layer on the second insulating layer.

As illustrated in FIGS. 1 and 3, the pixel electrode layer 90 integrally tiles and covers the second insulating layer (the GI layer 40 and the PAV layer 80). The recesses on the second insulating layer also have concave-convex 3D structures. The pixel electrode layer 90 is preferably made from transparent conductive material ITO.

As the light transmission area is completely covered by the pixel electrode layer 90, in the operation of the panel, the pixel electrode layer 90 in convex portions of the second insulating layer has high electric field strength and high penetration; and concave portions of the second insulating layer are stilled covered by the pixel electrode layer 90. Compared with the prior art, the electric field strength in the area is greatly improved, and hence the overall penetration of the pixel structure can be improved.

Accordingly, the method for manufacturing the pixel structure, provided by the present invention allows the first insulating layer 30 to fill the gaps of the M1 layer 20 and expose the M1 layer 20 by the forming of the planarized first insulating layer 30, eliminates the segment difference of the M1 layer 20, and hence eliminates the adverse effects on the manufacturing of subsequent layers due to segment difference. Therefore, the M1 layer 20 thicker than that of the traditional method can be prepared. Consequently, the wiring load of large-size panels can be effectively reduced; the resistance of signal lines can be reduced; the signal delay can be reduced; and the display quality can be improved.

Meanwhile, by adoption of the above structure, the second insulating layer with the concave-convex (or stripped) 3D structure is formed on the first insulating layer 30 of the light transmission area via a common mask without increasing the extra cost. Therefore, the pixel electrode layer 90 integrally tiles and covers the second insulating layer, so that the pixel electrode layer 90 can completely cover the light transmission area, and hence the penetration of pixels can be improved and the display quality can be finally improved.

The present invention further provides a display panel, which comprises a substrate and pixel structures. The pixel structure is disposed on the substrate and includes a patterned first metal layer and a planarized first insulating layer formed on the substrate. The first insulating layer is configured to fill gaps of the first metal layer and expose the surface of the first metal layer. The pixel structure described in the embodiment is the pixel structure provided by the above embodiment. No further description will be given here.

The display panel provided by the present invention allows the first insulating layer to fill the gaps of the first metal layer and expose the first metal layer by the forming of the planarized first insulating layer, eliminates the segment difference of the first metal layer, and hence eliminates the adverse effects on the manufacturing of subsequent layers due to segment difference. Therefore, the first metal layer thicker than that of the traditional method can be prepared. Consequently, the wiring load of large-size panels can be effectively reduced; the resistance of signal lines can be reduced; the signal delay can be reduced; and the display quality can be improved.

Meanwhile, by adoption of the above structure, the second insulating layer with the concave-convex (or stripped) 3D structure is formed on the first insulating layer 30 of the light transmission area via a common mask without increasing the extra cost. Therefore, the pixel electrode layer integrally tiles and covers the second insulating layer, so that the pixel electrode layer can completely cover the light transmission area, and hence the penetration of pixels can be improved and the display quality can be finally improved.

It should be understood that the foregoing is only the preferred embodiments of the present invention and not intended to limit the scope of the patent of the present invention and equivalent structures or equivalent process changes made by utilization of the content of the description and the accompanying drawings of the present invention and directly or indirectly applied in other relevant technical fields should fall within the scope of protection of the patent of the present invention in a similar way.

What is claimed is:

1. A method for manufacturing a pixel structure, comprising the following steps:
forming a patterned first metal layer on a substrate; and
forming a planarized first insulating layer on the substrate, in which the first insulating layer is configured to fill gaps of the first metal layer and expose a surface of the first metal layer.

2. The method for manufacturing the pixel structure according to claim 1, wherein the step of forming the planarized first insulating layer on the substrate includes:
forming a first insulating layer for covering the first metal layer on the substrate, in which the first insulating layer is configured to fill the gaps of the first metal layer; and
planarizing the first insulating layer, so that the surface of the first metal layer is exposed by the first insulating layer.

3. The method for manufacturing the pixel structure according to claim 2, wherein the step of planarizing the first insulating layer includes:
coating a negative photoresist layer on the first insulating layer;
performing development by taking the first metal layer as a mask, and removing the negative photoresist layer on the first metal layer to expose the first insulating layer; and
etching the first insulating layer, and removing the exposed first insulating layer on the first metal layer to expose the surface of the first metal layer.

4. The method for manufacturing the pixel structure according to claim 1, after the step of forming the planarized first insulating layer on the substrate, further comprising:
forming a second insulating layer provided with a plurality of recesses on the first insulating layer of a light transmission area; and
forming an integral pixel electrode layer on the second insulating layer, in which the pixel electrode layer integrally covers the second insulating layer.

5. The method for manufacturing the pixel structure according to claim 4, wherein the recesses are elongated; and the plurality of recesses are arranged in parallel.

6. The method for manufacturing the pixel structure according to claim 4, wherein the second insulating layer includes a gate insulator (GI) layer and a passivation (PAV) layer.

7. A pixel structure disposed on a substrate, comprising a patterned first metal layer and a planarized first insulating layer formed on the substrate, in which the first insulating layer is configured to fill gaps of the first metal layer and expose a surface of the first metal layer.

8. The pixel structure according to claim 7, wherein the pixel structure is provided with a light transmission area and further comprises a second insulating layer and a pixel electrode layer, in which
the second insulating layer is formed on the first insulating layer of the light transmission area and provided with a plurality of recesses; and
the pixel electrode layer is an integral structure and integrally covers the second insulating layer.

9. The pixel structure according to claim 8, wherein the recesses are elongated.

10. The pixel structure according to claim 8, wherein the plurality of recesses are arranged in parallel.

11. The pixel structure according to claim 8, wherein the second insulating layer includes a GI layer and a PAV layer.

12. A display panel, comprising a substrate and pixel structures disposed on the substrate, wherein the pixel structure includes a patterned first metal layer and a planarized first insulating layer formed on the substrate; and the first insulating layer is configured to fill gaps of the first metal layer and expose a surface of the first metal layer.

13. The display panel according to claim 12, wherein the pixel structure is provided with a light transmission area and further comprises a second insulating layer and a pixel electrode layer, in which
the second insulating layer is formed on the first insulating layer of the light transmission area and provided with a plurality of recesses; and
the pixel electrode layer is an integral structure and integrally covers the second insulating layer.

14. The display panel according to claim 13, wherein the recesses are elongated.

15. The display panel according to claim 13, wherein the plurality of recesses are arranged in parallel.

16. The display panel according to claim 13, wherein the second insulating layer includes a GI layer and a PAV layer.
